(19) United States
(12) Patent Application Publication
(10) Pub. No.: US 2022/0310862 A1
(43) Pub. Date: Sep. 29, 2022

(54) Flexible Solar Panel

(71) Applicant: XIAMEN DONESTY ECOMMERCE CO., LTD., Xiamen (CN)

(72) Inventor: Hao WANG, Xiamen (CN)

(21) Appl. No.: 17/393,425

(22) Filed: Aug. 4, 2021

(30) Foreign Application Priority Data
Mar. 26, 2021 (CN) 202120623664.9

(51) Int. Cl. H01L 31/05; H01L 31/048; H01L 31/02; H01L 31/0224

(52) U.S. Cl. CPC H01L 31/0512; H01L 31/048; H01L 31/02013; H01L 31/022425

(57) ABSTRACT

The disclosure provides a flexible solar panel, wherein a plurality of first main grid lines are arranged on a positive electrode surface of a solar cell body and are welded to a first solder strip; a plurality of second main grid lines are arranged on a negative electrode surface of the solar cell body and are welded to a second solder strip; a copper mesh is formed by a plurality of copper wires crossed transversely and vertically, and the copper mesh is composited on the positive electrode surface; a positive electrode EVA film is composited on the copper mesh; the solar cell body, the copper mesh and the positive electrode EVA film form a solar cell; a plurality of solar cells are connected in series and installed on a PCB board; a negative electrode EVA film covers the negative electrode surfaces of the solar cells.

### CROSS-REFERENCE TO RELATED PRESENT INVENTION(s)

The disclosure claims priority to and the benefit of Chinese Patent Present invention No. 202120623664.9, filed in the China National Intellectual Property Administration (CNIPA) on 26 Mar. 2021, which is incorporated herein by reference in its entirety.

### TECHNICAL FIELD

The disclosure relates to a flexible solar panel.

### BACKGROUND

A solar panel, also called as a solar cell module, is an assembly consisting of a plurality of solar cells. The solar cells are an important portion of the solar panel.

A common solar panel generally has a plurality of main grid lines on a negative electrode surface of a solar cell, the main grid lines are used for being welded to solder strips, and the diameter of the main grid lines is relatively great; and therefore, when the solar cell is bent, the solar cell is easy to break, and the broken part is separated from the solar cell body. As a result, the solar cell can no longer generate power in the broken part. Therefore, the solar panel made of the existing solar cell is usually cannot be bend, is not suitable to be installed on a curved surface, and is only suitable to be installed on a flat surface. Thus, the usage range of the existing solar panel is limited.

In addition, some solder strips of the solar cell are round wires, and the solder strips are fixed on the negative electrode surface of the solar cell by means of direct pressing, and therefore, the fixing firmness is poor and after being used for a long time, the solder strips are easy to lift up, causing the solar cell to be hollow and generate bubbles, and thus, water vapor is easy to infiltrate, causing the solar cell to delaminate and affecting the absorption of light.

### SUMMARY

The purpose of the disclosure is to propose a flexible solar panel, which can avoid a significant reduction in power generation caused by the breakage of a solar cell, facilitating installation, and expanding the usage range.

In order to achieve the purpose above, the technical solution of the disclosure is as follows:

a flexible solar panel includes a PCB board, a solar cell body, a copper mesh, a positive electrode EVA film, a negative electrode EVA film and a PET film; a plurality of first main grid lines are arranged on a positive electrode surface of the solar cell body, and are welded to a first solder strip, and a plurality of second main grid lines are arranged on a negative electrode surface of the solar cell body, and are welded to a second solder strip; the copper mesh is formed by a plurality of copper wires crossed transversely and vertically, and the copper mesh is composited on the positive electrode surface; the positive electrode EVA film is composited on the copper mesh, so that the copper mesh is fixed between the positive electrode surface of the solar cell body and the positive electrode EVA film; the solar cell body, the copper mesh and the positive electrode EVA film form a solar cell; a plurality of solar cells are connected in series and installed on the PCB board, and the positive electrode EVA film is attached to the PCB board; the negative electrode EVA film covers the negative electrode surfaces of the solar cells; and the PET film is laid on the negative electrode EVA film.

In the present embodiment, as the copper mesh has flexibility and impact resistance, the manufactured solar panel can have flexibility, ensuring the effective electrical connection of the solar cell body, and preventing the solar cell body from breaking; and if the solar cell body is broken, the broken part can be connected to the solar cell body by means of the copper mesh, so that the normal power generation of the solar panel can still be ensured. In addition, a diameter of the copper wires of the copper mesh is small, and the copper mesh is sheet-shaped, so that the copper mesh can be fixed between the positive electrode EVA film and the solar cell body by means of lamination, and therefore, the fixation is firm, the occurrence of delamination of the solar cell is avoided, and the effective operation of the solar cell is ensured.

A diameter of each of the plurality of first main grid lines is 0.5-1.6 mm, and a diameter of each of the plurality of second main grid lines is 0.5-1.6 mm.

A length of each of the plurality of first main grid lines arranged on the positive electrode surface is less than a length of each of the plurality of second main grid lines arranged on the negative electrode surface.

A diameter of each of the plurality of copper wires of the copper mesh is 0.01-0.05 mm.

A mesh number of the copper mesh is 2500-3000 mesh.

A thickness of the positive electrode EVA film is 0.08-0.1 mm.

A thickness of the negative electrode EVA film is 0.08-0.1 mm.

An overall thickness of each of the plurality of solar cells is 0.38-0.55 mm.

A thickness of the PCB board is 0.3-0.4 mm.

A thickness of the PET film is 0.8-1.1 mm.

A thickness of the flexible solar panel is 1.8-2.4 mm.

In the disclosure, after the structure abovementioned is used, a layer of the copper mesh is added on the positive electrode surface of the solar cell body, and the copper mesh fully covers the solar cell body to form a mesh structure on the positive electrode surface of the solar cell body. As the copper mesh is not only flexible but also impact resistant, a flexible solar panel can be made; the power generation of the solar cell will not drop due to breakage; even if a certain part of the solar cell is broken, the broken part will not be separated from the solar cell body, and with the help of the thin conductive copper wires of the copper mesh, the broken part can be connected to the solar cell body, so that the solar cell can still continue to generate power normally. The flexible solar panel of the disclosure is not only suitable for installation on a flat surface, but also can be installed on a curved surface, facilitating installation and expanding the usage range.

The disclosure will be further described in detail below in conjunction with the accompanying drawings and specific embodiments.

### BRIEF DESCRIPTION OF THE DRAWINGS

To describe the technical solutions in the embodiments of the disclosure more clearly, the accompanying drawings required for describing the embodiments are briefly introduced below. It should be understood that the following drawings illustrate only certain embodiments of the disclosure, and therefore, they should not be construed as limitations on the scope. Other relevant drawings may also be obtained according to these drawings without inventive efforts.

FIG. 1 shows a perspective exploded top view of the disclosure;

FIG. 2 shows a perspective exploded bottom view of the disclosure;

FIG. 3 shows a partial enlarged view of FIG. 1;

FIG. 4 shows a combined side view of the disclosure;

FIG. 5 shows a partially enlarged view of FIG. 4.

### DRAWING LABEL DESCRIPTION

a solar cell body 1; a positive electrode surface 11; a negative electrode surface 12; first main grid lines 21; second main grid lines 22; a first solder strip 31; a second solder strip 32; a copper mesh 4; a positive electrode EVA film 5; a negative electrode EVA film 6; a PET film 7; a PCB board 8; a solar cell 100; a flexible solar panel 200.

### DETAILED DESCRIPTION OF THE EMBODIMENTS

To make the objectives, technical solutions, and advantages of the embodiments of the disclosure clearer, the following clearly and completely describes the technical solutions in the embodiments of the disclosure with reference to the accompanying drawings in the embodiments of the disclosure. Obviously, the described embodiments are merely a part rather than all of the embodiments of the disclosure. All other embodiments obtained by those skilled in the art based on the embodiments of the disclosure without inventive efforts shall belong to the scope of protection of the disclosure. Therefore, the following detailed description for the embodiments of the disclosure as provided in the accompanying drawings is not intended to limit the scope of the disclosure, but is merely representative of selected embodiments of the disclosure. All other embodiments obtained by those of skilled in the art based on the embodiments of the disclosure without inventive efforts shall belong to the scope of protection of the disclosure.

In the description of the disclosure, it should be understood that, the orientations or position relationships indicated by the terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise” are based on the orientations or position relationships shown in the drawings, merely for facilitating description of the disclosure and simplifying the description, rather than indicating or implying that the indicated device or element must have a particular orientation, or be constructed and operated in a particular orientation, and thus, cannot be construed to the limitations on the disclosure.

In addition, terms “first”, “second” are only used for descriptive purpose, and cannot be understood as indicating or implying relative importance or implicitly indicating the plurality of the indicated technical feature. Thus, the feature defined by the term “first” or “second” may explicitly or implicitly indicating that there are one or more of the features. In the description of the disclosure, the term “a plurality of” means two or more than two, unless expressly defined otherwise.

In the disclosure, unless expressly stated and defined otherwise, terms such as “installed”, “coupled”, “connected”, “fixed” and the like should be understood in a broad sense, for example, it may be fixedly connected, and it may also be detachably connected or integrated; it may be mechanically connected or electrically connected; it may be directly connected or indirectly connected through an intermediary; and it may be the communication of the interiors of two elements or the interaction between two elements. A person of skilled in the art can understand the specific meanings of the described terms in the disclosure according to specific situations.

In the disclosure, unless expressly stated and defined otherwise, a first feature “on” or “under” a second feature may include the case where the first feature and the second feature are in direct contact, and may also include the case where the first feature and the second feature are not in direct contact, but in contact through another feature therebetween. Furthermore, the first feature “on”, “above”, and “over” the second feature include the cases where the first feature is right above and obliquely above the second feature, or merely indicate that the first feature is at a height higher than that of the second feature. The first feature “under”, “below”, and “underneath” the second feature include the cases where the first feature is right below and obliquely below the second feature, or merely indicate that the first feature is at a height lower than that of the second feature.

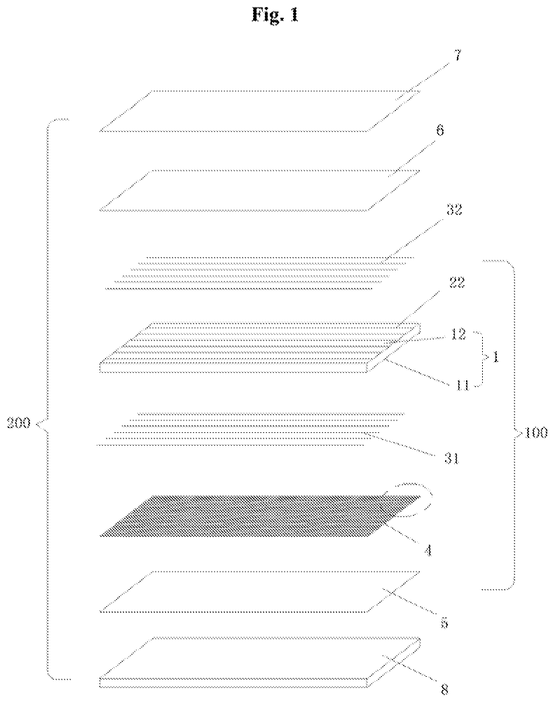

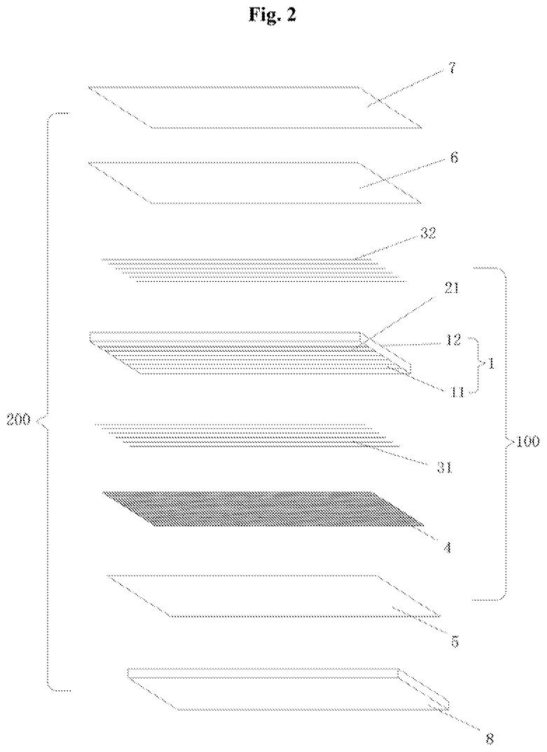

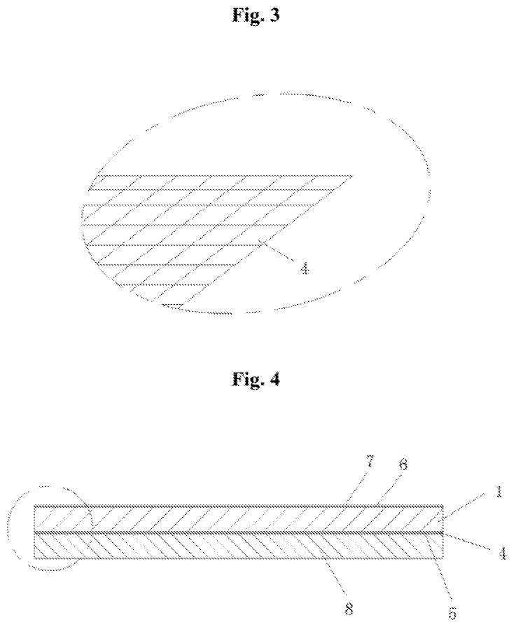

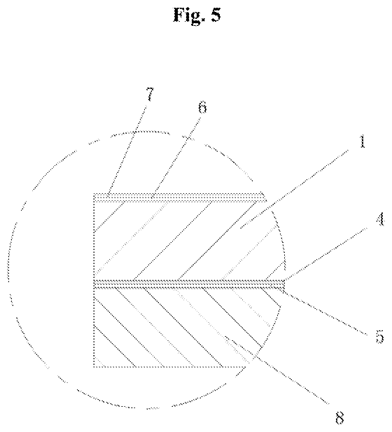

As shown in FIGS. 1-5, the disclosure provides a flexible solar panel 200, including a PCB board 8, a solar cell body 1, a copper mesh 4, a positive electrode EVA film 5, a negative electrode EVA film 6 and a PET film 7.

The solar cell body 1 has a positive electrode surface 11 and a negative electrode surface 12. A plurality of first main grid lines 21 are arranged on the positive electrode surface 11 of the solar cell body 1, a diameter of each of the plurality of first main grid lines 21 is 0.5-1.6 mm, and the plurality of first main grid lines 21 are welded to a first solder strip 31. A plurality of second main grid lines 22 are arranged on the negative electrode surface 12 of the solar cell body 1, a diameter of each of the plurality of second main grid lines 22 is 0.5-1.6 mm, and the plurality of second main grid lines 22 are welded to a solder strip 32. A length of each of the plurality of first main grid lines 21 arranged on the positive electrode surface 11 is less than a length of each of the plurality of second main grid lines 22 arranged on the negative electrode surface 12, so as to facilitate the electrical connection during subsequent processing of the solar panel.

The copper mesh 4 is formed by a plurality of copper wires crossed transversely and vertically. In an embodiment, a diameter of each of the plurality of copper wires is 0.01-0.05 mm, a mesh number of the copper mesh is 2500-3000 mesh, and the copper mesh 4 is composited on the positive electrode surface 11.

The positive electrode EVA film 5 is composited on the copper mesh 4, so that the copper mesh 4 is fixed between the positive electrode surface 11 of the solar cell body 1 and the positive electrode EVA film 5. In an embodiment, a thickness of the positive electrode EVA film 5 is 0.08-0.1 mm. EVA is a copolymer of ethylene and acetic acid.

The solar cell body 1, the copper mesh 4 and the positive electrode EVA film 5 form a solar cell 100. An overall thickness of the solar cell 100 is 0.38-0.55 mm.

A plurality of solar cells 100 are connected in series and installed on the PCB board 8, and the positive electrode EVA film 5 is attached to the PCB board 8. The PCB board 8 is configured to a bottom base material of the flexible solar panel. In an embodiment, a thickness of the PCB board 8 is 0.3-0.4 mm. The positive electrode EVA film 5 is used for preventing direct contact between the solar cell 100 and the PCB board 8.

The negative electrode EVA film 6 covers the negative electrode surface 12 of the solar cell 100. In an embodiment, a thickness of the negative electrode EVA film 6 is 0.08-0.1 mm.

The PET film 7 is laid on the negative electrode EVA film 6. PET is polyethylene terephthalate, and a transparent PET film 7 is configured to a lighting surface base material, so as to isolate the solar cell 100 from air, thereby achieving the purposes of waterproofing and air isolation. In an embodiment, a thickness of the PET film 7 is 0.8-1.1 mm.

In an embodiment, a thickness of the flexible solar panel 200 is 1.8-2.4 mm.

In the disclosure, as the copper mesh 4 fully covers the solar cell body 1, and the copper mesh 4 has flexibility and impact resistance, a novel bendable flexible solar panel 200 can be made, in which the effective electrical connection of the solar cell body 1 can be ensured, and the breakage of the solar cell body 1 can be avoided; and if the solar cell body is broken, the broken part can be connected to the solar cell body 1 by means of the copper mesh 4, so that the solar cell 100 is still allowed to continue to generate power normally.

The flexible solar panel 200 of the disclosure is not only suitable for installation on a flat surface, but also can be installed on a curved surface, thereby facilitating installation and expanding the usage range.

In addition, as each of the plurality of copper wires of the copper mesh 4 has a small diameter, and the copper mesh 4 is sheet-shaped, the copper mesh 4 can be fixed between the positive electrode EVA film 5 and the solar cell body 1 by means of lamination, so that the fixation is solider, the occurrence of delamination of the solar cell is avoided, and the effective operation of the solar cell is ensured.

The descriptions above are merely exemplary embodiments of the disclosure, but are not intended to limit the disclosure. Any modification, equivalent replacement, and improvement made without departing from the spirit and principle of the disclosure shall belong to the scope of protection of the disclosure.

What is claimed is:

1. A flexible solar panel, comprising:
a PCB board;
a plurality of solar cells, the plurality of solar cells are connected in series and installed on the PCB board, and each of the plurality of solar cells comprises a copper mesh;
a negative electrode EVA film, the negative electrode EVA film covers the plurality of solar cells.

2. The flexible solar panel according to claim 1, wherein the flexible solar panel further comprises:
a solar cell body, the solar cell body has a positive electrode surface and a negative electrode surface, and the negative electrode EVA film covers the negative electrode surface;
a positive electrode EVA film, the positive electrode EVA film is attached to the PCB board;

3. The flexible solar panel according to claim 2, wherein the positive electrode EVA film is composited on the copper mesh, so that the copper mesh is fixed between the positive electrode surface of the solar cell body and the positive electrode EVA film.

4. The flexible solar panel according to claim 3, wherein a plurality of first main grid lines are arranged on the positive electrode surface, and a plurality of second main grid lines are arranged on the negative electrode surface, and a length of each of the plurality of first main grid lines arranged on the positive electrode surface is less than a length of each of the plurality of second main grid lines arranged on the negative electrode surface.

5. The flexible solar panel according to claim 4, wherein the flexible solar panel further comprises two solder strips, the plurality of first main grid lines on the positive electrode surface and the plurality of second main grid line on the negative electrode surface are welded to one of the two solder strips respectively.

6. The flexible solar panel according to claim 3, wherein the copper mesh is fixed between the positive electrode EVA film and the solar cell body by means of lamination.

7. The flexible solar panel according to claim 1, wherein the copper mesh is formed by a plurality of copper wires crossed transversely and vertically.

8. The flexible solar panel according to claim 1, wherein the copper mesh is sheet-shaped.

9. The flexible solar panel according to claim 1, wherein
a mesh number of the copper mesh is 2500-3000 mesh; or
a diameter of each copper wire of the copper mesh is 0.01-0.05 mm; or
a mesh number of the copper mesh is 2500-3000 mesh and a diameter of each copper wire of the copper mesh is 0.01-0.05 mm.

10. The flexible solar panel according to claim 1, wherein the flexible solar panel further comprises a PET film, and the PET film is laid on the negative electrode EVA film.

11. The flexible solar panel according to claim 1, wherein the PCB board is configured to a bottom base material of the flexible solar panel.

12. A flexible solar panel manufacturing method, comprising:
step 1: first main grid lines on a positive electrode surface of a solar cell body and second main grid lines on a negative electrode surface of the solar cell body are welded to one of two solder strips respectively;
step 2: a copper mesh is fixed between a positive electrode EVA film and the solar cell body by means of lamination to form a solar cell;
step 3: a PCB board is configured to a bottom base material of the flexible solar panel, and a plurality of solar cells are connected in series and installed on the PCB board, and the positive electrode EVA film is attached to the PCB board;
step 4: a negative electrode EVA film covers the negative electrode surface;
step 5: a PET film is laid on the negative electrode EVA film as a lighting surface base material.

13. A flexible solar panel, comprising a PCB board, a solar cell body, a copper mesh, a positive electrode EVA film, a negative electrode EVA film and a PET film;
a plurality of first main grid lines are arranged on a positive electrode surface of the solar cell body, and are welded to a first solder strip; and
a plurality of second main grid lines are arranged on a negative electrode surface of the solar cell body, and are welded to a second solder strip;
the copper mesh is formed by a plurality of copper wires crossed transversely and vertically, and the copper mesh is composited on the positive electrode surface;
the positive electrode EVA film is composited on the copper mesh, so that the copper mesh is fixed between the positive electrode surface of the solar cell body and the positive electrode EVA film;
the solar cell body, the copper mesh and the positive electrode EVA film form a solar cell;
a plurality of solar cells are connected in series and installed on the PCB board, and the positive electrode EVA film is attached to the PCB board;
the negative electrode EVA film covers the negative electrode surfaces of the solar cells; and
the PET film is laid on the negative electrode EVA film.

14. The flexible solar panel according to claim 13, wherein a diameter of each of the plurality of first main grid lines is 0.5-1.6 mm, and a diameter of each of the plurality of second main grid lines is 0.5-1.6 mm.

15. The flexible solar panel according to claim 13, wherein a length of each of the plurality of first main grid lines arranged on the positive electrode surface is less than a length of each of the plurality of second main grid lines arranged on the negative electrode surface.

16. The flexible solar panel according to claim 13, wherein a thickness of the positive electrode EVA film is 0.08-0.1 mm; and a thickness of the negative electrode EVA film is 0.08-0.1 mm.

17. The flexible solar panel according to claim 13, wherein an overall thickness of each of the plurality of solar cells is 0.38-0.55 mm.

18. The flexible solar panel according to claim 13, wherein a thickness of the PCB board is 0.3-0.4 mm.

19. The flexible solar panel according to claim 13, wherein a thickness of the PET film is 0.8-1.1 mm.

20. The flexible solar panel according to claim 13, wherein a thickness of the flexible solar panel is 1.8-2.4 mm.
